(19) United States
(12) Patent Application Publication
(10) Pub. No.: US 2013/0019458 A1
(43) Pub. Date: Jan. 24, 2013

(54) SUPPORT SYSTEM FOR A SEMICONDUCTOR DEVICE

(71) Applicants: Jonathan M. Byars, Fountain Valley, CA (US); Theodore J. Copperthite, Laguna Hills, CA (US); H. Henry Von Tresckow, Oceanside, CA (US)

(72) Inventors: Jonathan M. Byars, Fountain Valley, CA (US); Theodore J. Copperthite, Laguna Hills, CA (US); H. Henry Von Tresckow, Oceanside, CA (US)

(73) Assignee: ORTHODYNE ELECTRONICS CORPORATION, Irvine, CA (US)

(21) Appl. No.: 13/577,462

(22) PCT Filed: Apr. 12, 2011
(86) PCT No.: PCT/US11/32028

§ 371 Date: Aug. 7, 2012

Related U.S. Application Data
(60) Provisional application No. 61/324,053, filed on Apr. 14, 2010.

(51) Int. Cl. H01L 21/60; H01L 21/683

(52) U.S. Cl. 29/559; 269/296

(57) ABSTRACT

A support system for a semiconductor device during a wire or ribbon bonding operation is provided. The support system includes a body portion defining an upper surface. The upper surface has an upper surface contact region configured to support at least a portion of a lower surface of a semiconductor device at a lower surface contact region during a wire or ribbon bonding operation. The support system also includes a plurality of protrusions on the upper surface contact region.

### CROSS-REFERENCE TO RELATED APPLICATIONS

This application claims the benefit of U.S. Provisional Application No. 61/324,053 filed on Apr. 14, 2010, the content of which is incorporated herein by reference.

### FIELD OF THE INVENTION

The present invention relates to wire and ribbon bonding operations, and more particularly, to support and retaining structures for semiconductor devices used in connection with wire and ribbon bonding operations.

### BACKGROUND OF THE INVENTION

In the processing and packaging of semiconductor devices, wire and ribbon bonding continue to be a widely used method of electrical interconnection between two locations within a package (e.g., between a die pad of a semiconductor die and a lead of a leadframe). For example, wire bonding machines (or ribbon bonding machines) are used to form wire loops (or ribbon interconnections) between respective locations to be electrically interconnected.

Semiconductor die are commonly supported by leadframes to transport them through various stages of the assembly process including ultrasonic bonding processes. A continuous trend in the semiconductor industry is that global markets demand smaller semiconductor devices at lower costs. One exemplary cost reduction strategy involves using less material in the devices, for example, using less copper material in the leadframe support structure which supports the semiconductor die. This strategy tends to lead to the creation of highly populated leadframes through the manufacturing process. Such highly populated leadframes tend to contain many rows and columns of semiconductor die and other components, where the leadframe portions are connected to the leadframe matrix by connecting portions such as small and thin tie bars. The density and small sizes of the leadframe components make properly constraining the portions of a semiconductor device (including leadframe portions, die portions, etc.) during ultrasonic wire or ribbon bonding processes very difficult.

In ultrasonic bonding, for example, a transducer drives a bonding tool to a predetermined vibratory frequency so that the bonding tool tip scrubs the bonding site to facilitate bonding. Since ultrasonic bonding is highly dynamic and energetic for large wire and ribbon bonding, a semiconductor device can be driven to high velocities similar in amplitude to the bonding tool's tip velocity during the bonding process. That is, the semiconductor device (including the die supported by the leadframe), may move (at least partially) with the vibrating bonding tool. When this occurs, the relative displacement between the tip of the bonding tool and the semiconductor die is decreased which may lead to poor quality bonds. Conventional structures and methods use clamping materials with low rates of wear under repeated ultrasonic bonding to increase their useful life. Such materials generally exhibit relatively low resistance to the velocity of the tool during bonding.

As illustrated in FIG. 3, support or retention structures (such as anvil 308 and finger clamps 328 are employed to clamp or retain semiconductor device 306 during a bonding operation. Clamps (e.g., finger clamps 328 or window clamps) are typically used to secure semiconductor device 306 (including leadframe 300 carrying semiconductor die 302) against support structure 308 during a bonding operation. Such clamping and/or retention of semiconductor device 306 is intended to minimize induced movement of semiconductor device 306 during ultrasonic bonding. Unfortunately, poor clamping (which may result from the density and arrangement of the components) tends to lead to an unreliable bonding process, and therefore bonded components of a poor quality. Further, movement of such clamps 328 relative to leadframe 300 during bonding may damage and/or mark leadframe 300.

Thus, it would be desirable to provide improved bonding support systems to minimize or eliminate movement of semiconductor devices relative to the support systems during bonding to improve bond quality.

### SUMMARY OF THE INVENTION

According to an exemplary embodiment of the present invention, a support system for a semiconductor device during a wire or ribbon bonding operation is provided. The support system includes a body portion defining an upper surface that includes an upper surface contact region configured to support at least a portion of a lower surface of a semiconductor device at a lower surface contact region during the wire or ribbon bonding operation. The support system also includes a plurality of protrusions on the upper surface contact region.

According to another exemplary embodiment of the present invention, a support system for a semiconductor device during a wire or ribbon bonding operation is provided. The support system includes a lower body portion defining an upper surface, the upper surface being configured to support at least a portion of a bottom surface of a semiconductor device during the wire or ribbon bonding operation. The support system also includes an upper body portion defining a lower surface configured to contact at least a portion of a top surface of the semiconductor device at a contact region during the wire or ribbon bonding operation. The support system further includes a plurality of protrusions on the lower surface.

According to yet another exemplary embodiment of the present invention, a method of supporting a semiconductor device during a wire or ribbon bonding operation is provided. The method includes the step of providing a body portion that defines an upper surface including an upper surface contact region having a plurality of protrusions. The upper surface contact region is configured to support at least a portion of a lower surface of the semiconductor device at a lower surface contact region during the wire or ribbon bonding operation. The method further includes the step of supporting at least the portion of the lower surface of the semiconductor device at the lower surface contact region with the upper surface contact region such that the lower surface contact region is deformed by the plurality of protrusions.

According to yet another exemplary embodiment of the present invention, a method for supporting a semiconductor device during a wire or ribbon bonding operation is provided. The method includes the step of providing a lower body portion that defines an upper surface configured to support at least a portion of a bottom surface of the semiconductor device during the wire or ribbon bonding operation. The method also includes the step of providing an upper body portion that defines a lower surface configured to contact at least a portion of a top surface of the semiconductor device at a contact region during the wire or ribbon bonding operation. The lower surface includes a plurality of protrusions. The method further includes the step of deforming the top surface with the plurality of protrusions during the wire or ribbon bonding operation.

### BRIEF DESCRIPTION OF THE DRAWINGS

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIGS. 1A-1B are a plan view of a leadframe and an enlarged plan view of a portion of the leadframe;

FIG. 2 is a side sectional block diagram view of a wire or ribbon bonding tool system;

FIG. 3 is a side sectional view of a prior art support system;

FIG. 4A is a side sectional view of a support system in accordance with an exemplary embodiment of the present invention;

FIG. 4B is a side sectional view of a portion of the support system of FIG. 4A;

FIG. 4C is a front sectional view of a portion of the support system of FIG. 4A rotated 90 degrees with respect to FIG. 4B;

FIGS. 5A-5C are a side sectional view, an enlarged side sectional view, and an enlarged plan view of another support system in accordance with an exemplary embodiment of the present invention;

FIGS. 5D-5E are plan and perspective views of portions of another support system in accordance with an exemplary embodiment of the present invention;

FIGS. 6A-6C are a side sectional view, a top down view, and an enlarged top down view, of another support system in accordance with an exemplary embodiment of the present invention;

FIG. 7 is a plan view of another support system in accordance with an exemplary embodiment of the present invention; and

FIGS. 8A-8B are a plan view, and an enlarged plan view, of a surface of a portion of a support system in accordance with another exemplary embodiment of the present invention.

### DETAILED DESCRIPTION OF THE INVENTION

The terms “wire”, “ribbon”, and “conductive material” are used herein to generically describe the material bonded by a wire bonding system. It is understood that a wire bonding system may bond a wire material, a ribbon material, etc., as is desired in the given application. Thus, it is understood that these terms are used interchangeably and are not intended to be limiting with respect to each other.

“Plastic shearing” refers to a deformation when parallel surfaces slide past one another, for example, the surface structures and the leadframe surface contacting them as described herein. Such plastic shearing may be irreversible and, as such, markings on the leadframe surface are visible after the bonding operation.

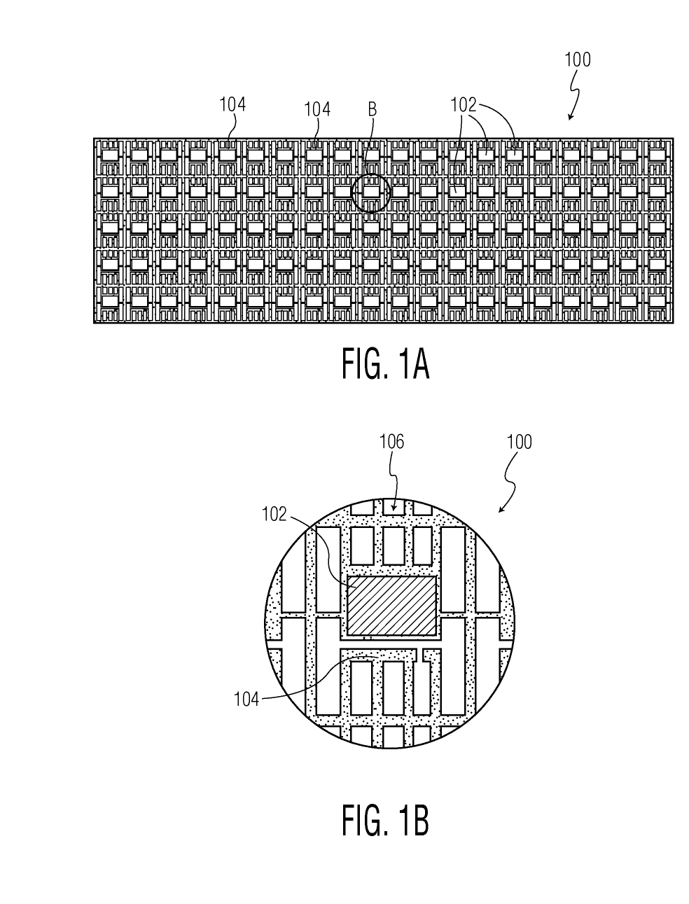

FIG. 1A is a plan view of a portion of an exemplary leadframe 100. Leadframe 100 supports a plurality of semiconductor die 102 (e.g., power semiconductor die), and includes leads 104. Leadframe 100 may serve to transport die 102 through various assembly stages including, for example, ultrasonic bonding. FIG. 1B is an enlarged portion of FIG. 1A at circle “B” and illustrates one semiconductor device 106 including die 102 supported by a portion of leadframe 100.

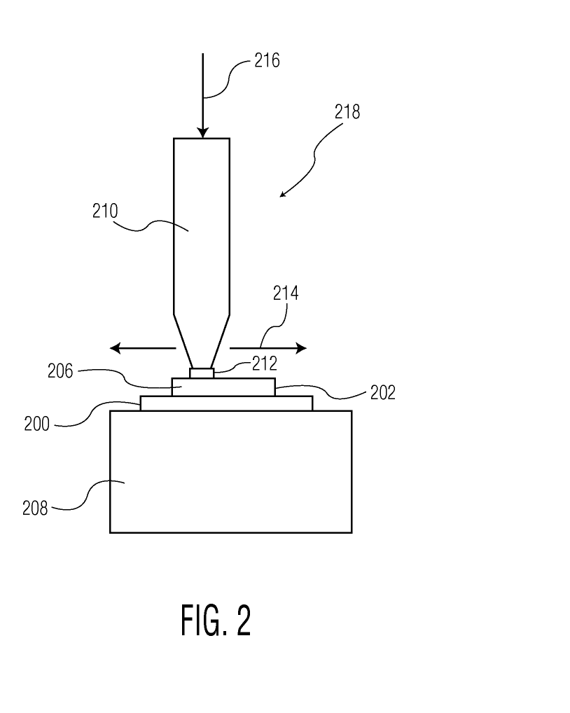

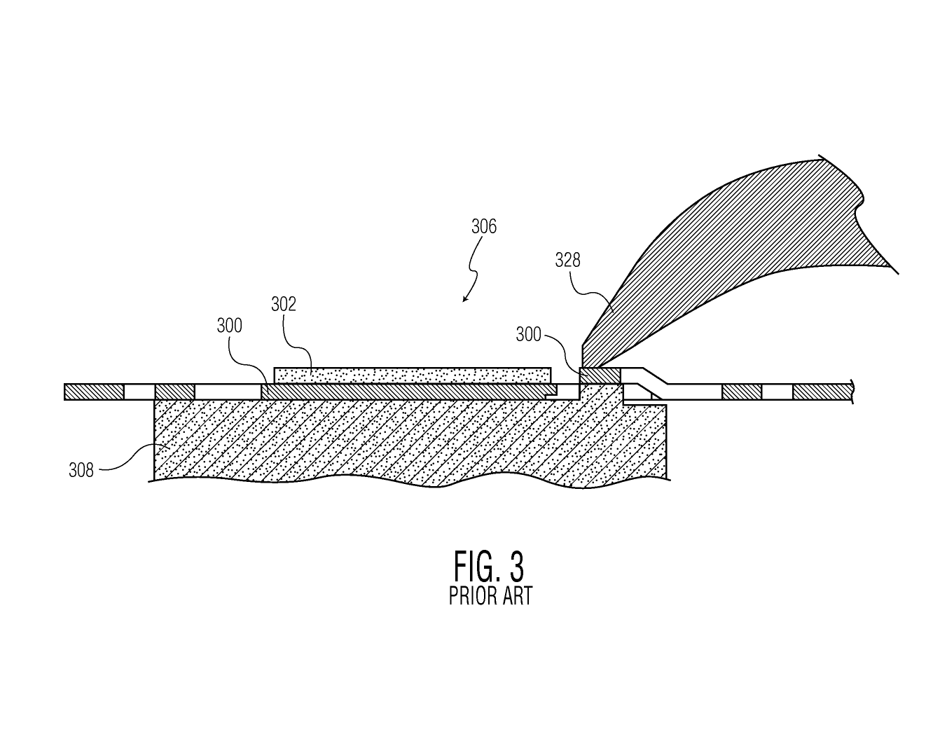

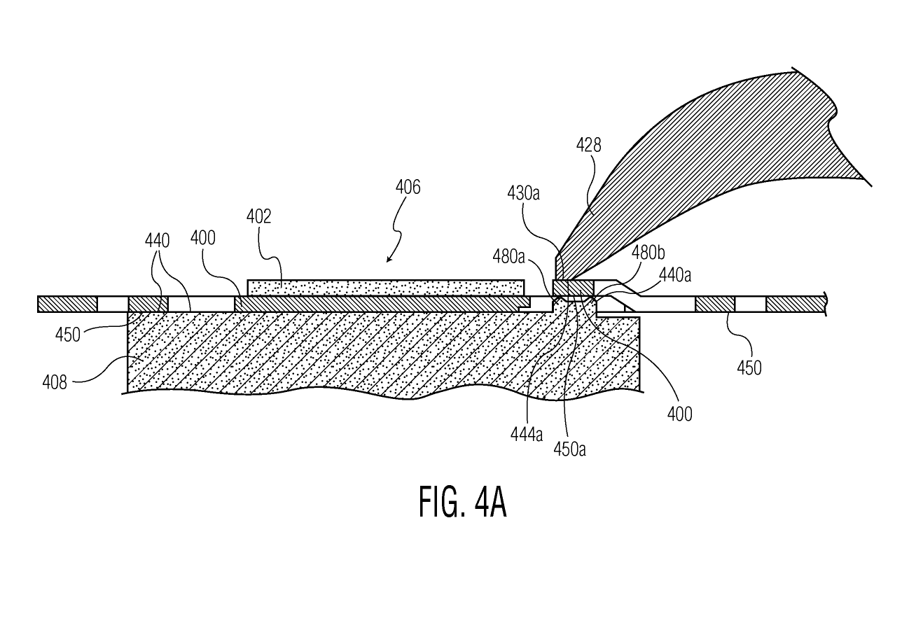

FIG. 2 illustrates semiconductor device 206 being bonded by bonding tool 210 of wire bonding system 218. Semiconductor device 206 includes semiconductor die 202 supported by substrate 200 (e.g., a copper leadframe or other die support structure). Semiconductor device 206 is supported by supporting structure 208 (e.g., anvil 208). Bonding tool 210 bonds conductive material 212 (e.g., wire or ribbon) to semiconductor package 206 to provide electrical interconnection, for example, between die 202 and substrate 200.

Bonding tool 210 is engaged in a transducer (e.g., an ultrasonic transducer, not shown) of wire bonding system 218. The transducer causes lateral vibratory movement 214 of bonding tool 210 in, for example, the X-direction or the Y-direction. Bonding tool 210 is pressed against wire or ribbon 212 with a downward force 216. The transducer is activated to cause bonding tool 210 to vibrate at 214 to assist in bonding conductive material 212 to the bonding location on die 202 (or a bonding location on substrate 200).

If desired, the force of vibration may be in the same order of magnitude as downward force 216 (e.g., where exemplary ranges for the force are: between about 0.01 to 4.0 N; between about 1.0 to 30.0 N; and between about 1.0 to 100.0 N) for ribbon bonding by bonding tool 210. This vibratory loading depends upon the material properties and the frictional coupling at the interface between bonding tool 210 and semiconductor device 206. Exemplary ranges for lateral vibration 214 are about 0.5 to 20 μm, and about 0.5 to 6.0 μm.

According to various exemplary embodiments of the present invention, a support system/structure (and method) is provided to reduce movement of a semiconductor device (e.g., a die supported by a leadframe) relative to a support and/or clamping structure during ultrasonic bonding. Surface features may be formed/provided on the support structure and/or clamping structure(s) that contact the semiconductor device in certain regions to resist vibratory movement induced by the bonding tool. For example, surface features (e.g., pyramidal structures, pointed features, etc.) may be formed on/into the support/clamping structures by machining, electrical discharge machining, laser ablation, etc. In another example, such surface features may consist of particles embedded in a coating on the support/clamping structures (e.g., diamond particles embedded in a nickel coating). Other example surface features and their methods of formation will be noted hereafter.

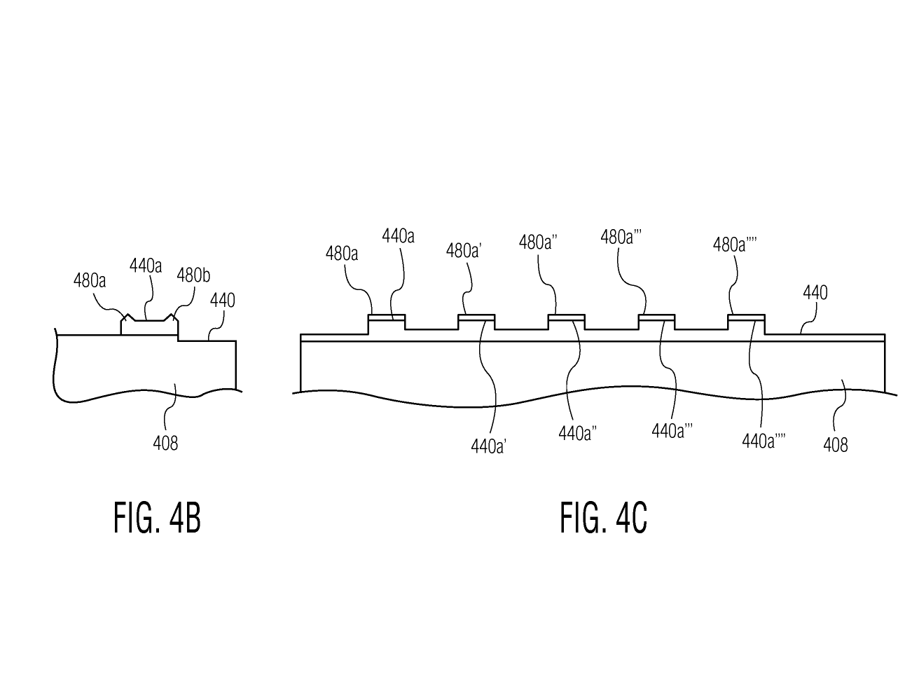

FIG. 4A illustrates semiconductor device 406 including semiconductor die 402 and leadframe 400. A lower support body portion 408 (e.g., anvil 408) is moved upwardly by, for example, an anvil cam (not shown) such that anvil upper surface 440 contacts lower surface 450 of leadframe 400. Portion 440a of anvil upper surface 440 includes a plurality of surface structures 480a, 480b (that may be protrusions and recesses formed into portion 440a) that contact portion 450a of leadframe 400 directly under clamp finger 428 (see below). For example, surface structures 480a, 480b may be a series of pointed structures.

An upper support body portion, such as clamp fingers 428 (one is shown for simplicity) may then be moved downwardly by, for example, a finger cam (not shown) so that lower surface 444a of finger clamp 428 contacts, and applies pressure to, upper surface portion 430a of leadframe 400.

It is noted that surface structures (like structures 480a, 480b) may instead be on lower surface 444a of finger clamps 428, which may result in a simplified design of body portion 408. Also, additional surface structures (e.g., having a structure similar to surface structures 480a, 480b) may also be located on upper surface 440 of anvil/support structure 408 that may or may not be directly under the area(s) to be bonded. For example, additional surface structures may be placed directly under where the bonding tool will be pressed against leadframe 400/semiconductor device 406 with a downward force or load normal to upper surface 440 of leadframe 400. As one skilled in the art would appreciate, the bonding tool force would create a compression force to at least partially embed (or further embed) such surface structures, and/or to cause plastic deformation of leadframe 400 at such localized area(s) (see below).

FIG. 4B is an enlarged view of a portion of FIG. 4A proximate anvil upper surface portion 440a of anvil 408 having surface structures 480a, 480b on anvil upper surface 440. FIG. 4C is a view of FIG. 4B rotated 90 degrees and illustrates a series of surface structures 480a, 480a′, 480a″, 480a″′, 480a″″ formed on respective upper surface portions 440a, 440a′, 440a″, 440a′″, 440″″ over upper surface 440 of anvil 408. (It is noted that corresponding surface structures 480b, et al., are masked by their corresponding surface structures 480a, et al.) Such surface structures 480a, 480b, et al., may be formed directly below where clamps 428 are configured to be positioned, or where a bonding tool is configured to be positioned to form bonds on device 406, or another location as desired. During such clamping and ultrasonic bonding, respective surface structures 480a, 480b; 480a′, 480b′; etc., may function as described herein to decrease/eliminate movement of leadframe 400 and die 402 relative to anvil 408.

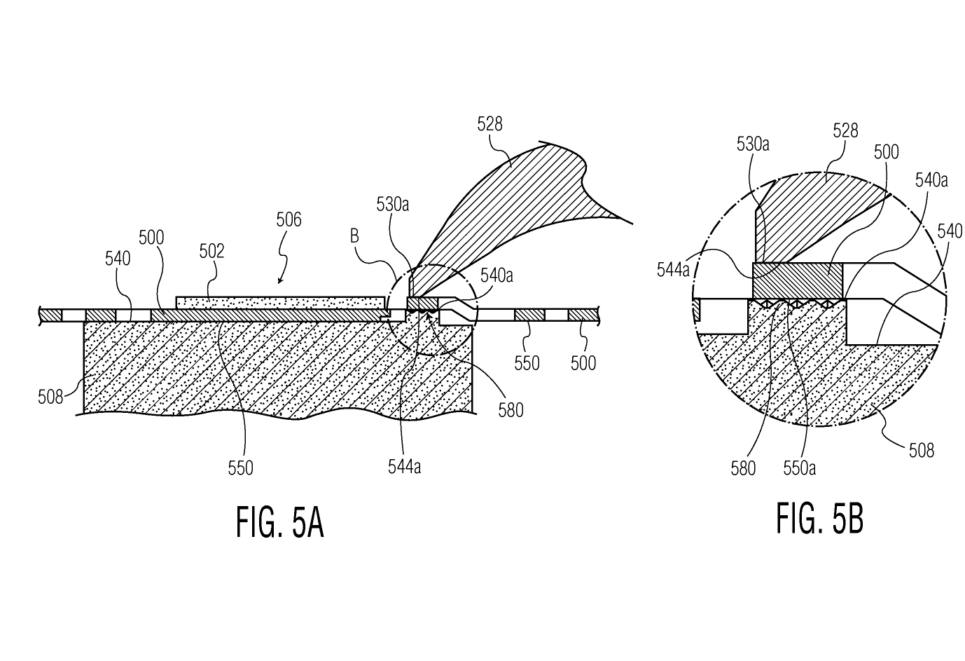

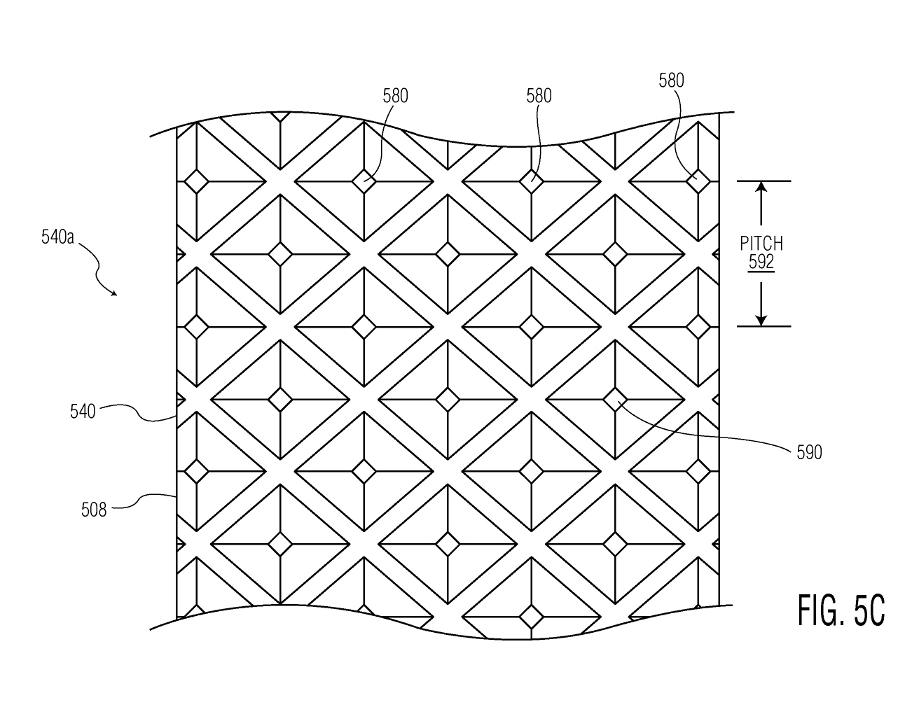

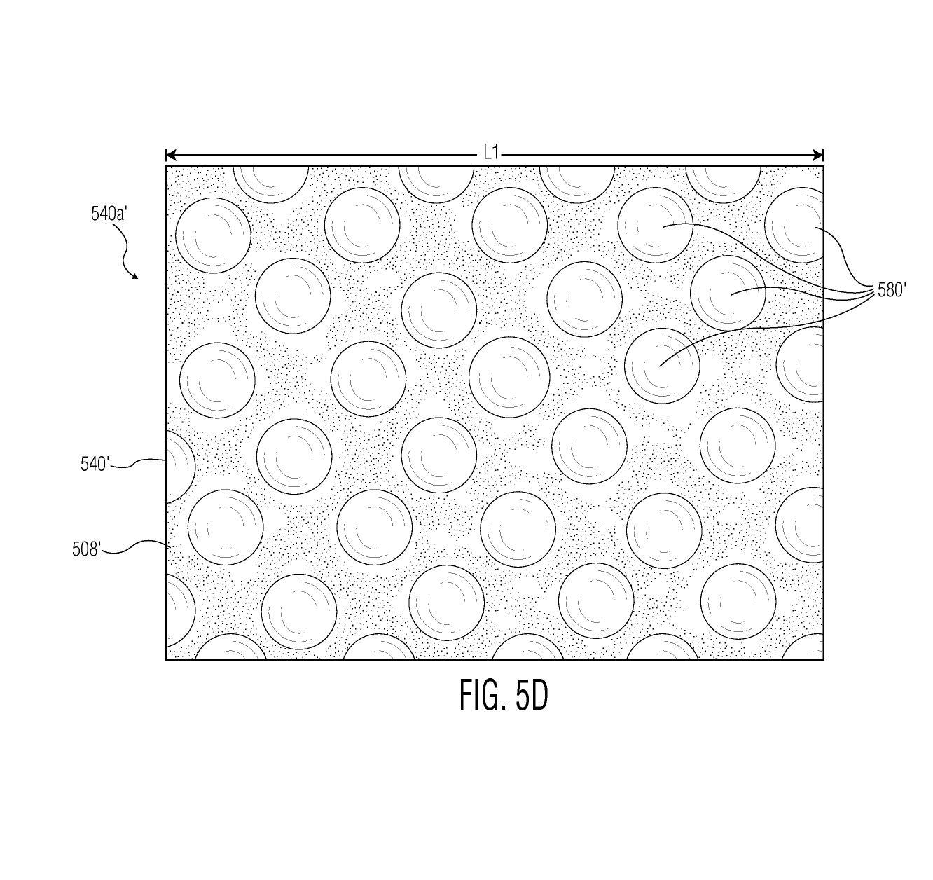

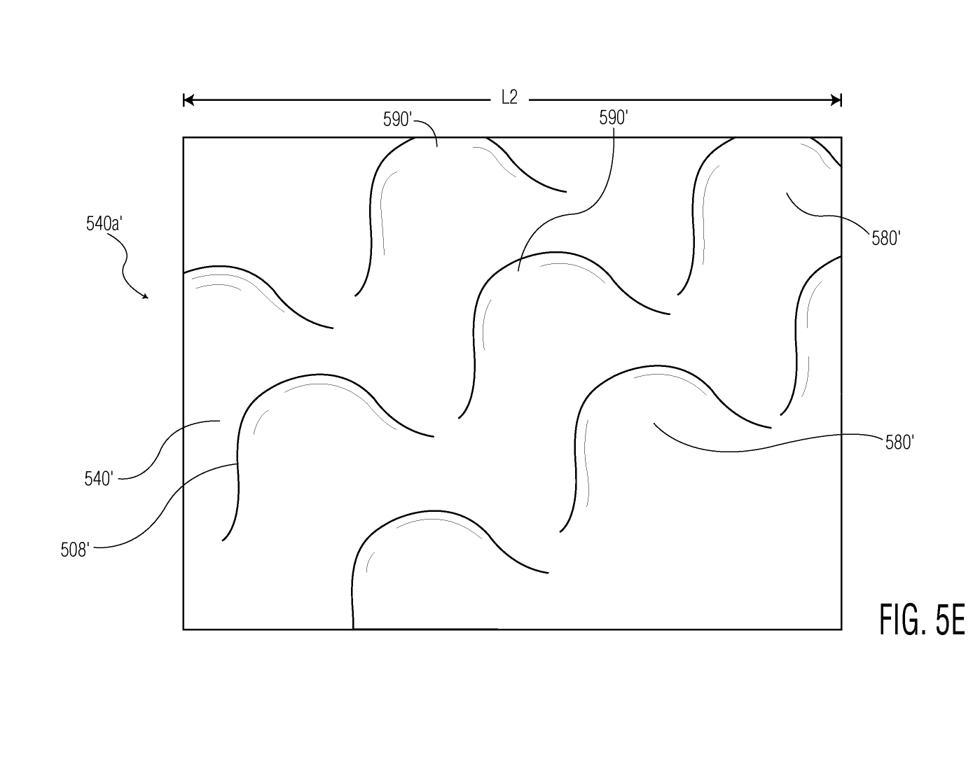

FIGS. 5A-5B (with FIG. 5B being an enlarged portion of FIG. 5A at circle “B”) illustrate another exemplary support structure. Surface structures 580 (that may be protrusions and/or recesses) are formed on portion 540a of anvil upper surface 540. Surface structures 580 contact portion 550a of leadframe 500 directly under clamp finger 528. Anvil 508 may be moved upwardly by anvil cam (not shown), for example, to engage semiconductor device 506, including semiconductor die 502 and leadframe 500, so that upper surface 540 of anvil 508 contacts lower surface 550 of leadframe 500. Surface structures 580 on portion 540a of anvil upper surface 540 contact leadframe portion 550a directly under finger clamp 528 (see below).

An upper support body portion, such as clamp fingers 528 (one is shown for simplicity), may then be moved downwardly by, for example, a finger cam (not shown) so that lower surface 544a of finger clamp 528 contacts upper surface portion 530a of leadframe 500 and applies pressure at each finger clamp 528.

FIG. 5C is a top down view of exemplary surface structures 580 formed into portion 540a of upper surface 540 of anvil 508. Surface structures 580 are pyramidal in shape and have upper top surfaces 590 and are separated by a distance, or pitch 592. Pyramidal surface structures 580 may be arranged in a waffle-type arrangement as shown. The area of top surfaces 590, and the degree of pitch 592, may be selected on the basis of the materials of the semiconductor device, anvil, and clamping fingers as well as the clamping force of the clamping fingers and a downward force, or normal load of the bonding tool employed, as well as on other factors and conditions as noted herein.

While FIG. 5C provides a substantially symmetric and/or uniform array of surface structures 580, it is clear that such structures may vary in shape and size. For example, if structures 580 are formed by selectively removing material from a surface (e.g., a ceramic support surface), the resultant structures 580 may be non-uniform and somewhat random in shape. More specifically, FIGS. 5D-5E are a top down view, and a perspective view, of exemplary surface structures 580′. In each FIG. 5D-5E, pyramidal structures 580′ are formed on portion 540a′ of upper surface 540′ of anvil 508′. FIG. 5E more clearly illustrates substantially flat upper surfaces 590′ of surface structures 580′. An example length L1 in FIG. 5D may be on the order of 300 microns, and an example length L2 in FIG. 5E may be on the order of 100 microns.

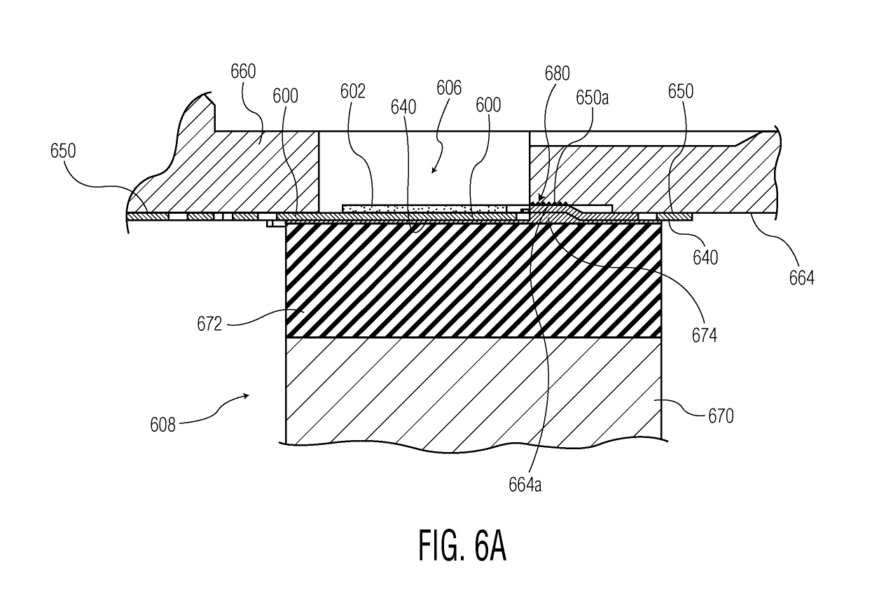

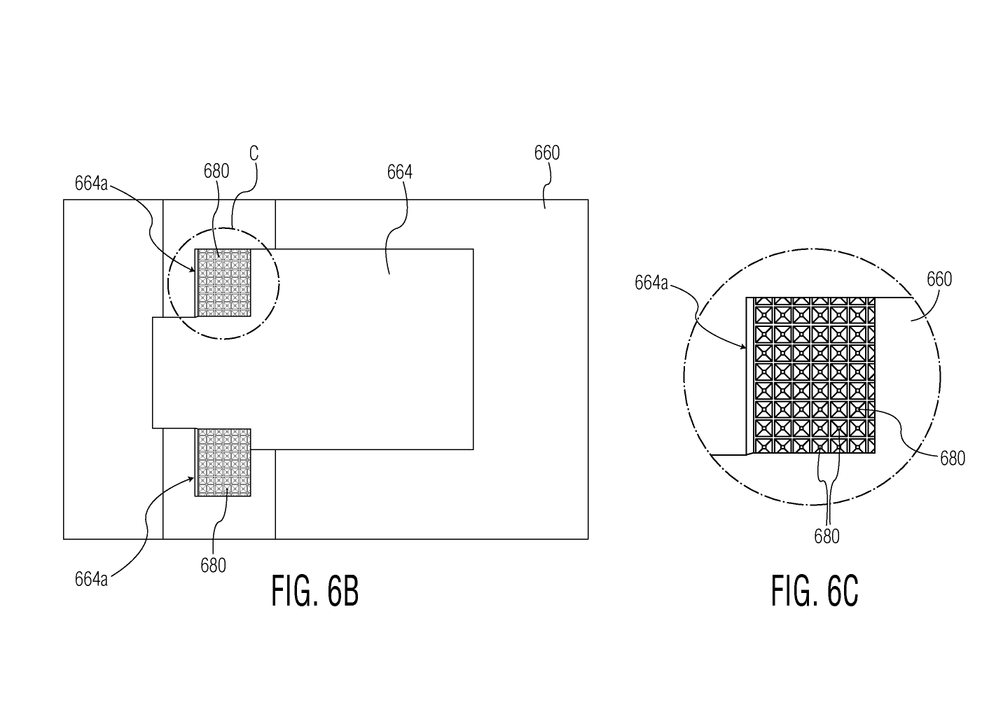

FIG. 6A illustrates exemplary window clamp 660 having surface structures 680 (that may be protrusions and recesses) formed on portion 664a of window clamp lower surface 664. Surface structures 680 contact upper surface portion 650a of leadframe 600. Semiconductor device 606, including semiconductor die 602 and leadframe 600, lie over support structure 608 (e.g., anvil 608). Anvil 608 includes a lower stiff base 670, an upper compliant layer 672 and a hard plate 674 overlying compliant layer 672. Exemplary materials used to form lower stiff base 670 may be metals, ceramics, or plastics; exemplary materials used to form upper compliant layer 672 may be an elastomer such as urethane or silicon rubber; and exemplary materials used to form hard plate 674 may be metals, such as stainless steel or tool steel.

Window clamp 660 may be lowered (e.g., by a window clamp cam) to contact upper surface 650 of leadframe 600 of semiconductor device 606. Window clamp surface structures 680 in portion 664a of lower surface 664 contact leadframe portion 650a on leadframe upper surface 650. Then, anvil 608 may be raised (e.g., by an anvil cam) until hard plate 674 (e.g., stainless steel plate 674), contacts bottom surface 640 of leadframe 600. Stiff base 670 may then be further raised upwardly to compress complaint layer 672 so that a substantially even pressure may be applied against leadframe bottom surface 640 in the areas being clamped.

FIG. 6B is a bottom up view of window clamp 660 illustrated in FIG. 6A. Window clamp 660 includes surface structures 680 in portions 664a of window clamp lower surface 664. FIG. 6C is an enlarged portion of FIG. 6B at circle “B” and illustrates surface structures 680 in portion 664a of window clamp 660 as being pyramidal in shape (e.g., such as in FIGS. 5C-5E).

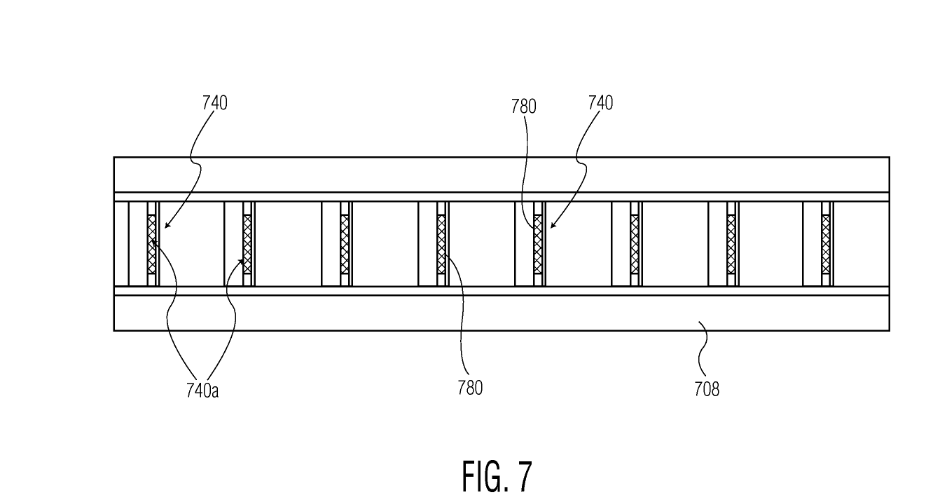

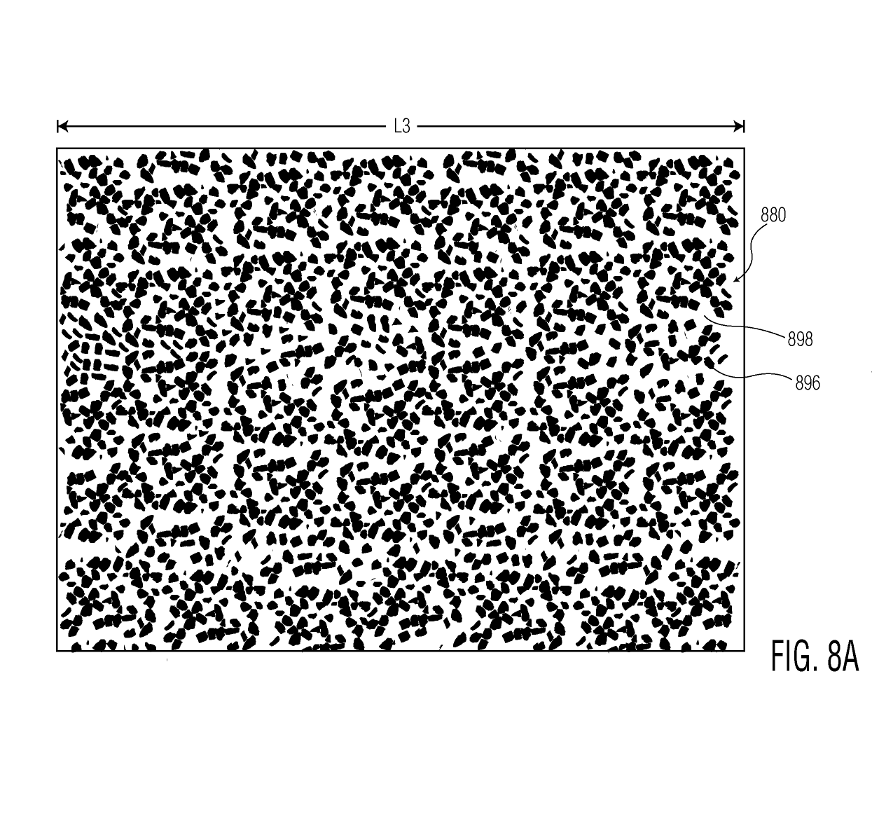

FIG. 7 illustrates exemplary support structure 708 (e.g., anvil 708) including eight raised constraining features 740 (e.g., similar to raised features/portions 440a, 540a, 540a′ previously described with respect to FIGS. 4A-4C, 5A-5C, and 5D-5E, respectively) with contact surface portions 740a having surface structures 780 formed thereon. Anvil 708 will thus accommodate eight semiconductor devices (e.g., see FIGS. 1A-1B). A portion of a leadframe (a lead) rests on the peak of raised feature 740 so that surface features 780 will contact the lower surface of the device/leadframe. It is noted that raised features 740 may be provided to align with raised portions of a leadframe. Surface features 780 may or may not be proximate the bonding sites used by the ultrasonic bonding tool and may comprise, for example, a diamond grit (diamond particles embedded in a nickel plating), a plurality or series of pointed structures, a plurality or series of pyramidal structures, etc. (see, e.g., FIGS. 4A-4C, 5A-5C, 5D-5E, 6A-6C, and 8A-8B).

It is noted that surface structures 480a, 480b, 580, 580′, 680, 780 illustrated and described in the exemplary embodiments may collectively comprise, without limitation, abrasive particles, a series of machined structures, a series of electrical discharge machined (EDM) structures in conductive materials, a series of laser ablation structures, a series of pyramidal structures, a series of pointed structures, etc.

In one example, the surface structures may be machined directly into the anvil, clamp fingers and/or window clamp (e.g., see FIGS. 5C-5E). In such instances, the anvil or clamp may be comprised of a hard and wear resistant material, for example, hardened steel, tungsten carbide, alumina ceramic, partially stabilized zirconia ceramic, silicon nitride, or other similar materials. If conductive materials are employed, then an EDM (electrical discharge machining) process may be used to create the surface structures. For both conductive and non-conductive materials, a grinding, ultrasonic or laser machining process, for example, may be used to create the surface structures. Also rough surface finishes may be used (e.g., ceramics with rough surface finishes, ceramic grit coatings, etc.).

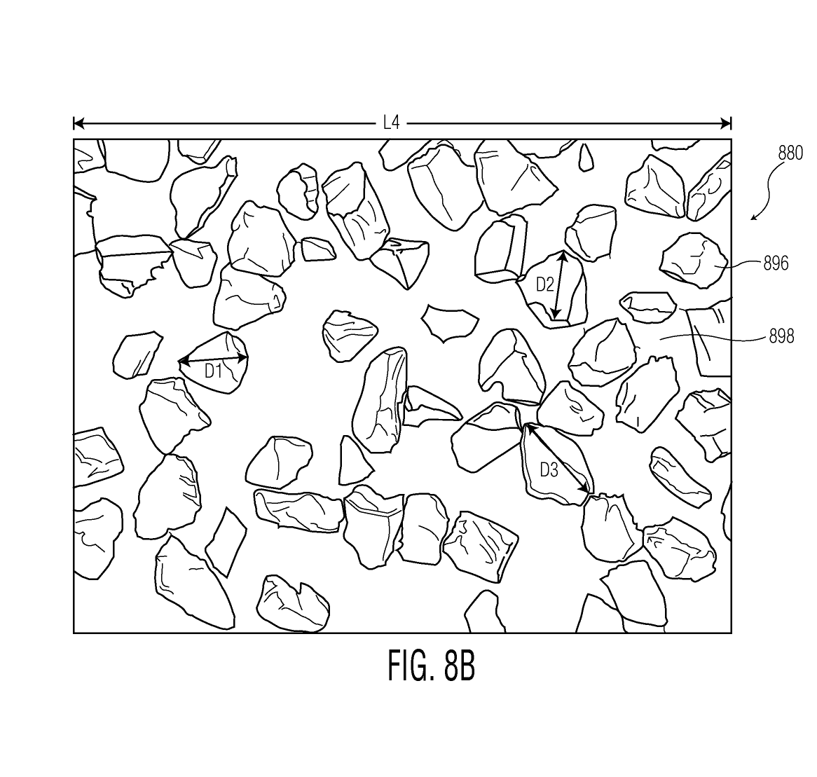

FIG. 8A is an illustration of a surface of an exemplary support structure including grip coating 880. Coating 880 includes, for example, diamond particles 896 of varying sizes embedded in a nickel plating 898. FIG. 8B is an enlarged view of a portion of FIG. 8A and more clearly illustrates diamond particles 896 in nickel plating 898 to comprise diamond grip coating 880. An example length L3 in FIG. 8A may be on the order of 1 millimeter, and an example length L4 in FIG. 8B may be on the order of 100 microns. Of course, particles other than diamond particles, and coatings other than nickel, are contemplated.

Exemplary sizes (e.g., D1, D2, and D3 in FIG. 8B) of diamond particles 896 are from about 10 to 30 um, about 5 to 50 um, and from about 5 to 100 um. Other examples of the material of particles 896 include tungsten carbide particles or other similarly hard and wear resistant particles embedded in a plating/coating (e.g., a nickel plating/coating).

For each exemplary embodiment, surface structures 480a, 480b; 580; 580′; 680; 780; 880, may be designed such that the contact stress between the leadframe lower surface portion and the upper surface of the anvil portion may be elevated in that localized area. With the additional contact stress caused by, for example, the contact pressure of finger clamps essentially directly above the leadframe contact portion (or by a window clamp), compression may occur causing the leading portion of the surface structures to rest beyond the datum surface defined by the lower surface of the leadframe/semiconductor device. For the exemplary embodiment having surface structures 680 on the lower surface of a window clamp or the possible use of surface structures 680 in the lower surface of finger clamp(s), the combined compression of the leadframe against the lower anvil similarly causes the leading portion of surface structures 680 to rest beyond the datum surface defined by the upper surface of the leadframe/semiconductor device. Thus, the greater the contact stress at the surface feature region(s), the greater the penetration of the surface features into the surface of the semiconductor device/leadframe and the greater the resistance to the velocity of the bonding tool. That is, at least a portion of the leading surfaces of the surface structures may be embedded into the leadframe/semiconductor device at the leadframe contact portion (e.g., by a small amount, such as from about 1 to 10 um).

Placement of the selected surface structures may depend upon, for example, the leadframe and package structure, manufacturing requirements, clamp placement and bond placement. When the surface structures of the present invention are placed on the anvil, the resistance to movement/velocity may be achieved, for example, in areas of clamp finger contact, directly under the bond locations during bonding, or other areas as desired. When the surface structures of the present invention are located on the bottom surface of a window clamp, their location may be limited to a specific area; however, in certain applications it may be desired that the surface structures be widely distributed on the bottom surface of a window clamp to engage varying types of devices (e.g., leadframe devices). The surface features may also be located at, for example, areas close to positions of ultrasonic bonding to achieve maximum plastic shearing (see below).

When an ultrasonic bonding tool is engaged with a leadframe/semiconductor device to form a bond, the leadframe contact portion of the lower or upper surface of the leadframe/device may move, or attempt to move, relative to the anvil, window clamp and/or finger clamps having the surface features. The geometry of such surface structures, in conjunction with the elevated contract stress, may cause the leadframe/device to resist the velocity caused by the ultrasonic excitation in the localized area of the bonding tool. This may result in dissipation of energy and plastic shearing of the leadframe material at the interface between the surface structures and the leadframe contact portion. During continued application of such ultrasonic excitation during the bonding process, more material may be sheared and the surface features may penetrate further into the surface of the device/leadframe. A pattern, marking, or marring on the leadframe at the leadframe contact portion also may occur where such plastic shearing results from ultrasonic bonding.

Careful selection of the materials used to clamp/retain the semiconductor device during a bonding operation may result in high rates of resistance to the velocity induced by a bonding tool as well as low rates of wear under the ultrasonic loading of the tool. This may allow for longer clamp/retaining structure life and better resistance to movement/velocity of the device during ultrasonic bonding which may lead to a simplification of the clamp/retaining structure design and a more robust and stable bonding process.

Thus, the amount of contact stress required to cause plastic shearing (e.g., to dissipate energy and resist the velocity of the bonding tool) may be dictated by the properties of the leadframe. Leadframes may be made of work hardened copper-iron alloys. The approximate yield strength of exemplary leadframe materials ranges from about 300 to 600 N/m². Therefore, the contact stress may need to exceed this yield strength to cause static penetration (embedding) into the leadframe. The degree of such static penetration may be dictated by the hardness of the material and the impact energy imparted on the leadframe during a clamping cycle, as well as the actual geometry of the surface (penetrating/embedding) features. An exemplary range of static penetration (embedding) is between 1 um to 10 um, although other ranges are contemplated.

Further, the amount of pressure applied to the semiconductor device/leadframe during a clamping operation may be up to and slightly beyond the yield strength of the material from which the device/leadframe is composed. However, an operator may generally apply as little pressure as is necessary to achieve stable bonding, for example, so as to extend the life of the clamp tooling. Many leadframes are made of copper, copper with a nickel plating, copper alloys (such as copper iron alloys), etc. The yield strength of 99.9% pure copper is about 70 MPa, and the yield strength of an example copper iron alloy is about 140 MPa range. For an exemplary clamping device employing 2 to 20 clamp fingers per device, each clamp finger may exert a force between about 4 to 60N and an example bonding tool may exert a force from about 2 to 37N. Of course, such force parameters may vary widely. Regarding the bonding tool force, this may vary based on whether the bonding tool is bonding a small wire, a large wire, or a conductive ribbon. Exemplary ranges for the force applied by the bonding tool are: between about 0.01 to 4.0 N; between about 1.0 to 30.0 N; and between about 1.0 to 100.0 N.

Generally, the higher the contact stress, the greater the resistance to movement/velocity in the localized area of surface feature contact as the surface feature(s) tends to penetrate further into the leadframe or device surface. However, as the contact area is reduced so as to increase the contract stress within the localized area, wear life may decrease, potentially causing a greater wear rate which will reduce the useful life of the design.

As will be appreciated by those skilled in the art, any of the surface structures/protrusions described herein (e.g., surface structures 480a, 480b; 580; 580′; 680; 780) may be formed to be part of a unitary piece of material (e.g., a support structure such as an anvil for supporting a leadframe portion during bonding, an upper layer of the support structure, etc.). Further, the surface structures/protrusions may be separate structures integrated into another structure (e.g., integrated into a support structure for supporting a leadframe portion during bonding).

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A support system for a semiconductor device during a wire or ribbon bonding operation, the support system comprising:
a body portion defining an upper surface, the upper surface including an upper surface contact region configured to support at least a portion of a lower surface of a semiconductor device at a lower surface contact region during a wire or ribbon bonding operation; and
a plurality of protrusions on the upper surface contact region.

2. The support system of claim 1 wherein the plurality of protrusions are configured to deform the lower surface contact region during the wire or ribbon bonding operation.

3. The support system of claim 1 wherein the plurality of protrusions are configured to at least partially embed into the lower surface contact region during a clamping operation before the wire or ribbon bonding operation.

4. The support system of claim 1 wherein the plurality of protrusions comprise diamond particles.

5. The support system of claim 1 wherein the plurality of protrusions include a series of surface structures.

6. The support system of claim 5 wherein the series of surface structures comprise a series of pyramidal structures.

7. The support system of claim 5 wherein the series of surface structures comprise a series of pointed structures.

8. The support system of claim 1 wherein the plurality of protrusions include at least one of:
abrasive particles,
a series of machined structures,
a series of electrical discharge machined (EDM) structures,
a series of structures formed by laser ablation,
a series of pyramidal structures, and
a series of pointed structures.

9. The support system of claim 1 wherein the semiconductor device includes a leadframe, the leadframe defining the lower surface.

10. A support system for a semiconductor device during a wire or ribbon bonding operation, the support system comprising:
a lower body portion defining an upper surface, the upper surface being configured to support at least a portion of a bottom surface of a semiconductor device during a wire or ribbon bonding operation;
an upper body portion defining a lower surface, the lower surface being configured to contact at least a portion of a top surface of the semiconductor device at a contact region of the semiconductor device during the wire or ribbon bonding operation; and
a plurality of protrusions on the lower surface.

11. The support system of claim 10 wherein the plurality of protrusions being configured to deform the top surface during the wire or ribbon bonding operation.

12. The support system of claim 10 wherein the plurality of protrusions are configured to at least partially embed into the top surface during a clamping operation before the wire or ribbon bonding operation.

13. The support system of claim 10 wherein the plurality of protrusions comprise diamond particles.

14. The support system of claim 10 wherein the plurality of protrusions are a series of surface structures formed on the lower surface.

15. The support system of claim 14 wherein the series of surface structures comprise a series of pyramidal structures.

16. The support system of claim 14 wherein the series of surface structures comprise a series of pointed structures.

17. The support system of claim 10 wherein the plurality of protrusions are defined by
abrasive particles,
a series of machined structures,
a series of electrical discharge machined (EDM) structures,
a series of structures formed by laser ablation,
a series of pyramidal structures, or
a series of pointed structures.

18. The support system of claim 10 wherein the upper body portion includes a window clamp.

19. The support system of claim 10 wherein the upper body portion includes a series of clamp fingers.

20. The support system of claim 10 further comprising
a second plurality of protrusions on the upper surface, wherein the bottom surface is supported at a second contact region of the semiconductor device during the wire or ribbon bonding operation, the second plurality of protrusions being configured to deform the bottom surface during the wire or ribbon bonding operation.

21. The support system of claim 20 wherein the semiconductor device includes a leadframe, the leadframe defining the top surface and the bottom surface.

22. The support system of claim 10 wherein the semiconductor device includes a leadframe, the leadframe defining the top surface.

23. A method of supporting a semiconductor device during a wire or ribbon bonding operation, the method comprising the steps of:
a) providing a body portion, the body portion defining an upper surface including an upper surface contact region having a plurality of protrusions, the upper surface contact region configured to support at least a portion of a lower surface of a semiconductor device at a lower surface contact region during a wire or ribbon bonding operation; and
b) supporting at least the portion of the lower surface of the semiconductor device at the lower surface contact region with the upper surface contact region such that the lower surface contact region is deformed by the plurality of protrusions.

24. The method of claim 23 wherein during step b) the plurality of protrusions are configured to at least partially embed into the lower surface contact region during a clamping operation before the wire or ribbon bonding operation.

25. The method of claim 23 wherein the plurality of protrusions comprise diamond particles.

26. The method of claim 23 wherein the plurality of protrusions are a series of surface structures.

27. The method of claim 26 wherein the series of surface structures is a series of pyramidal structures.

28. The method of claim 26 wherein the series of surface structures is a series of pointed structures.

29. The method of claim 23 wherein the plurality of protrusions include at least one of:
abrasive particles,
a series of machined structures,
a series of structures formed by electrical discharge machining (EDM),
a series of structures formed by laser ablation,
a series of pyramidal structures, or
a series of pointed structures.

30. The method of claim 23 wherein the semiconductor device includes a leadframe, the leadframe defining the lower surface.

31. A method for supporting a semiconductor device during a wire or ribbon bonding operation, the method comprising the steps of:
a) providing a lower body portion, the lower body portion defining an upper surface being configured to support at least a portion of a bottom surface of a semiconductor device during a wire or ribbon bonding operation;
b) providing an upper body portion, the upper body portion defining a lower surface being configured to contact at least a portion of a top surface of the semiconductor device at a contact region during the wire or ribbon bonding operation, the lower surface including a plurality of protrusions; and
c) deforming the top surface with the plurality of protrusions during the wire or ribbon bonding operation.

32. The method of claim 31 wherein the plurality of protrusions is configured to at least partially embed into the top surface during a clamping operation before the wire or ribbon bonding operation.

33. The method of claim 31 wherein the plurality of protrusions comprise diamond particles.

34. The method of claim 31 wherein the plurality of protrusions are a series of surface structures formed on the lower surface.

35. The method of claim 34 wherein the series of surface structures comprise a series of pyramidal structures.

36. The method of claim 34 wherein the series of surface structures comprise a series of pointed structures.

37. The method of claim 31 wherein the plurality of protrusions include at least one of:
abrasive particles,
a series of machined structures,
a series of structures formed by electrical discharge machining (EDM),
a series of structures formed by laser ablation,
a series of pyramidal structures, or
a series of pointed structures.

38. The method of claim 31 wherein the upper body portion includes a window clamp.

39. The method of claim 31 wherein the upper body portion includes a series of clamp fingers.

40. The method of claim 31 wherein the upper surface includes a second plurality of protrusions, the upper surface being configured to contact at least a portion of the bottom surface of the semiconductor device at a second contact region during the wire or ribbon bonding operation, the second plurality of protrusions being configured to deform the bottom surface at the second contact region during the wire or ribbon bonding operation.
